(19) United States
(12) Patent Application Publication
(10) Pub. No.: US 2023/0387346 A1
(43) Pub. Date: Nov. 30, 2023

(54) SEMICONDUCTOR STRUCTURE AND MANUFACTURING METHOD THEREFOR, AND LIGHT-EMITTING DEVICE AND MANUFACTURING METHOD THEREFOR

(71) Applicant: ENKRIS SEMICONDUCTOR, INC., Suzhou, Jiangsu (CN)

(72) Inventor: Liyang ZHANG, Suzhou, Jiangsu (CN)

(73) Assignee: ENKRIS SEMICONDUCTOR, INC., Suzhou, Jiangsu (CN)

(21) Appl. No.: 18/029,855

(22) PCT Filed: Nov. 18, 2020
(86) PCT No.: PCT/CN2020/129794

§ 371 Date: Mar. 31, 2023

(51) Int. Cl. H01L 33/10; H01L 33/20; H01L 33/32; H01L 33/46; H01L 33/00; H01L 33/62

(52) U.S. Cl. CPC H01L 33/10; H01L 33/20; H01L 33/32; H01L 33/46; H01L 33/0075; H01L 33/62

(57) ABSTRACT

The present application provides a semiconductor structure and a manufacturing method therefor, and a light-emitting device and a manufacturing method therefor. The semiconductor structure includes a substrate, a first semiconductor layer, an isolation layer, an active layer, a second semiconductor layer, a first electrode and a second electrode. The second semiconductor layer is a conductive DBR structure. The first semiconductor layer includes a flat portion, a first protrusion and a second protrusion stacked sequentially in a vertical direction, the second protrusions correspond one-to-one to the first through-holes, and the second protrusions are arranged at intervals, and the side surface of the second protrusions are beveled. The active layer, the second semiconductor layer, and the first electrode are provided on the second protrusions of the first semiconductor layer stacked in sequence. The isolation layer is provided with a second through-hole, and the second electrode is formed in the second through-hole.

### CROSS REFERENCE TO RELATED APPLICATIONS

This application is a US National Phase of a PCT Application No. PCT/CN2020/129794 filed on Nov. 18, 2020, the entire contents of which are incorporated herein by reference in their entireties.

### TECHNICAL FIELD

The present application relates to the field of semiconductors, especially to a semiconductor structure and a manufacturing method therefor, and a light-emitting device and a manufacturing method therefor.

### BACKGROUND

At present, light-emitting devices (LEDs) are usually manufactured by using gallium nitride-based materials, and the epitaxial sidewall of the manufactured LED has a vertical structure. However, due to the vertical structure and the high refractive index of gallium nitride, most of the light is reflected when reaching the surface of the LED, so that a large amount of light is confined to the inside of the LED chip, resulting in low light-emitting efficiency.

Therefore, how to further improve the light-emitting efficiency of LEDs is still an urgent problem to be solved.

### SUMMARY

The present application provides a semiconductor structure, a method for manufacturing the semiconductor structure, a light-emitting device and a method for manufacturing the light-emitting device, which can improve the light-emitting efficiency of the light-emitting device.

To achieve the above purpose, according to a first aspect of an embodiment of the present application, a semiconductor structure is provided. The semiconductor structure includes a substrate, a first semiconductor layer, an isolation layer, an active layer, a second semiconductor layer, a first electrode and a second electrode. The first semiconductor layer has a conductivity type opposite to a conductivity type of the second semiconductor layer, and the second semiconductor layer is a conductive Distributed Bragg Reflector (DBR) structure.

The first semiconductor layer includes a flat portion, first protrusions and second protrusions stacked sequentially in a vertical direction. The flat portion is formed on the substrate, the isolation layer is formed on the flat portion and includes first through-holes in a vertical direction, the first protrusions are formed in the first through-holes respectively, one of the second protrusions is formed on one of the first protrusions, the second protrusions correspond to the first through-holes respectively, the second protrusions are spaced apart from each other, and a side surface of each of the second protrusions is a bevel.

The active layer, the second semiconductor layer, and the first electrode are stacked sequentially on the second protrusions of the first semiconductor layer.

The isolation layer is further provided with a second through-hole in the vertical direction, and the second electrode is formed in the second through-hole and is connected to the first semiconductor layer.

Optionally, the conductive DBR structure is a porous conductive DBR structure, the porous conductive DBR structure includes one or more first porous conductive layers and one or more second porous conductive layers which are alternately stacked and formed after electrochemical corrosion, where one or more first porous conductive layers each has first holes, the one or more second porous conductive layers each has second holes, and one of the first holes has a diameter different from a diameter of one of the second holes.

Optionally, materials of the one or more first porous conductive layers and one or more the second porous conductive layers are gallium nitride-based materials.

Optionally, an angle between the side surface of one of the second protrusions and a horizontal plane is a first angle, and the first angle have a degree range of 40 degrees to 70 degrees.

Optionally, a sidewall of one of the first through-holes is a bevel, and the sidewall of the one of the first through-holes is inclined in a same direction as the side surface of one of the second protrusions.

Optionally, one of the second protrusions is shaped as a cone, a truncated circular cone, a pyramid or a truncated pyramid.

Optionally, a transparent electrode is further provided between the second semiconductor layer and the first electrode.

Optionally, a material of the first semiconductor layer is a gallium nitride-based material.

According to a second aspect of an embodiment of the present application, a light-emitting device is provided, and the light-emitting device includes a semiconductor structure as described above. The light-emitting device further includes a circuit board and a wavelength conversion dielectric layer.

The circuit board is provided with a first solder pad and a second solder pad, the first electrode of the semiconductor structure is connected to the first solder pad on the circuit board, and the second electrode of the semiconductor structure is connected to the second solder pad on the circuit board.

A surface of the substrate away from the first semiconductor layer is provided with third through-holes, the third through-holes correspond to the first through-holes respectively, and the wavelength conversion dielectric layer is provided in at least one of the third through-holes.

Optionally, the sidewall of one of the third through-holes is a bevel.

Optionally, the light-emitting device further includes a reflective layer, and the reflective layer is covered on the sidewalls of the third through-holes.

According to a third aspect of an embodiment of the present application, a method for manufacturing a semiconductor structure is provided for manufacturing a semiconductor structure as described above. The method for manufacturing a semiconductor structure includes the following steps:

S1: forming the flat portion of the first semiconductor layer on the substrate; forming the isolation layer on the flat portion of the first semiconductor layer, forming the first through-holes in the isolation layer; forming the first protrusions of the first semiconductor layer in the first through-holes respectively, and forming the second protrusions of the first semiconductor layer on the first protrusions respectively;

S2: forming the active layer on the second protrusions of the first semiconductor layer;

S3: forming the second semiconductor layer having the conductivity type opposite to the conductivity type of the first semiconductor layer on the active layer; and

S4: forming the first electrode on the second semiconductor layer; forming the second through-hole in the isolation layer, and forming the second electrode connected to the first semiconductor layer in the second through-hole, thereby forming the semiconductor structure.

Optionally, in step S2, through selective growing, forming the active layer on the second protrusions of the first semiconductor layer.

In step S3, through selective growing, forming the second semiconductor layer having a conductive type opposite to a conductive type of the first semiconductor layer on the active layer.

In step S4, through selective growing, forming the first electrode on the second semiconductor layer.

According to a fourth aspect of an embodiment of the present application, a method for manufacturing a light-emitting device is provided. The method for manufacturing the light-emitting device includes the method for manufacturing a semiconductor structure as described above, and the method for manufacturing the light-emitting device further includes:

S5: mounting the semiconductor structure to the front side of a circuit board, the circuit board being provided with a first solder pad and a second solder pad, connecting the first electrode of the semiconductor structure to the first solder pad on the circuit board, and connecting the second electrode of the semiconductor structure to the second solder pad on the circuit board;

S6: forming third through-holes on a surface of the substrate away from the first semiconductor layer, where the third through-holes correspond to the first through-holes respectively;

S7: forming a wavelength conversion dielectric layer in at least one of the third through-holes.

Optionally, a sidewall of one of the third through-holes is a bevel.

Optionally, after step S6 and before step S7, the method further includes:

forming a reflection layer on a sidewall of one of the third through-holes.

### BRIEF DESCRIPTION OF THE DRAWINGS

FIG. 1 is a schematic diagram of a cross-sectional structure of the semiconductor structure according to Embodiment 1 of the present application.

FIG. 2 is a partially enlarged view of part A in FIG. 1.

FIG. 3 is a schematic diagram of a cross-sectional structure of the second semiconductor layer of the semiconductor structure according to Embodiment 1 of the present application.

FIG. 4(a)-FIG. 4(g) are process flow diagrams of a method for manufacturing the semiconductor structure according to Embodiment 1 of the present application.

FIG. 5 is a schematic diagram of a cross-sectional structure of the light-emitting device according to Embodiment 2 of the present application.

FIG. 6(a)-FIG. 6(d) are process flow diagrams of the method for manufacturing the light-emitting device according to Embodiment 2 of the present application.

### DETAILED DESCRIPTION OF THE EMBODIMENTS

Exemplary embodiments will be described herein in detail, examples of which are represented in the accompanying drawings. The following description relates to the accompanying drawings, the same numerals in different accompanying drawings indicate the same or similar elements unless otherwise indicated. The embodiments described in the following exemplary embodiments do not represent all embodiments consistent with the present application. Rather, they are only examples of devices and methods that are consistent with some aspects of the present application, as detailed in the appended claims.

### Embodiment 1

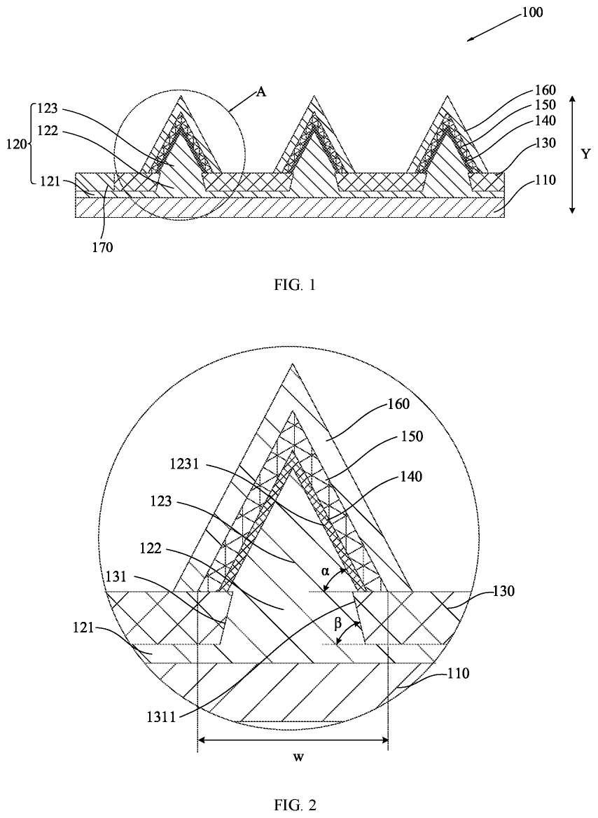

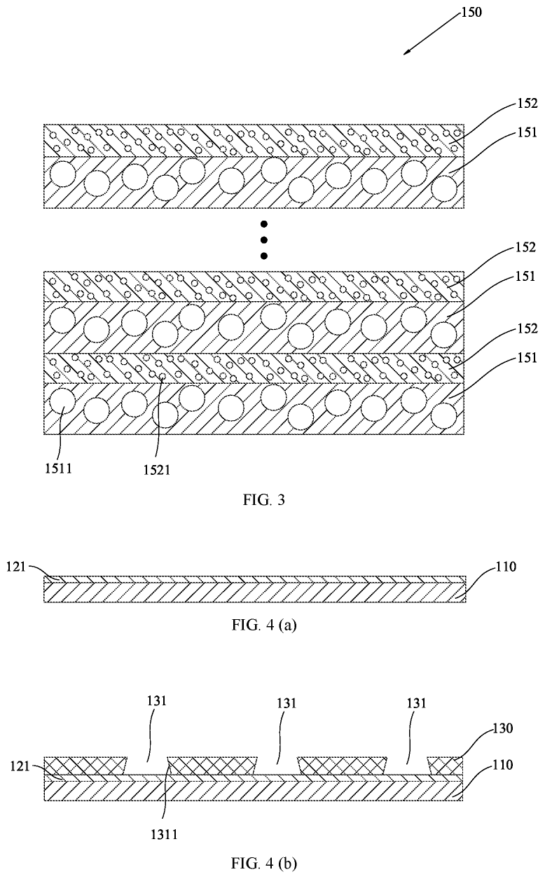

As shown in FIGS. 1 and 2, the embodiment provides a semiconductor structure 100. The semiconductor structure 100 includes a substrate 110, a first semiconductor layer 120, an isolation layer 130, an active layer 140, a second semiconductor layer 150, a first electrode 160, and a second electrode 170. The first semiconductor layer 120 has a conductivity type opposite to the second semiconductor layer 150, for example, when the first semiconductor layer 120 is a P-type semiconductor layer, the second semiconductor layer 150 is an N-type semiconductor layer; or, when the first semiconductor layer 120 is an N-type semiconductor layer, the second semiconductor layer 150 is a P-type semiconductor layer.

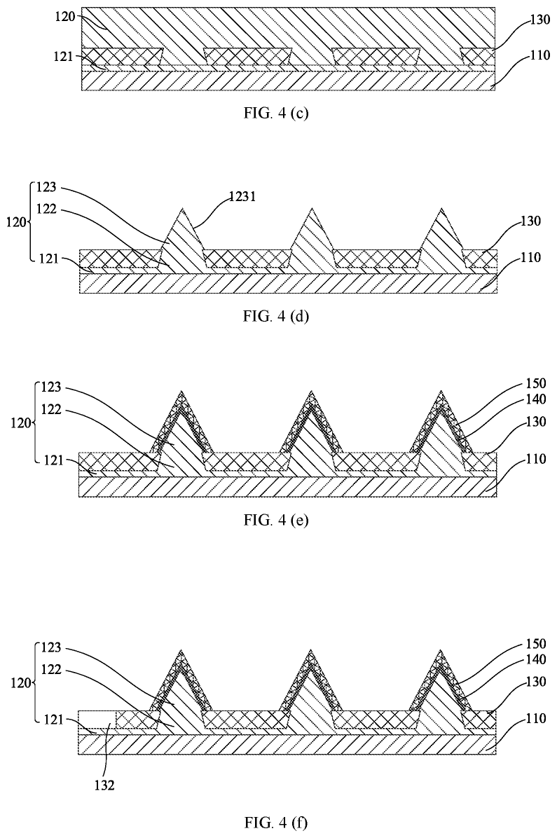

As shown in FIG. 3, the second semiconductor layer 150 is a conductive Distributed Bragg Reflection (DBR) structure, and the conductive DBR structure is a porous conductive DBR structure. In some examples, the porous conductive DBR structure includes one or more first porous conductive layers 151 and one or more second porous conductive layers 152 which are alternately stacked and formed after electrochemical corrosion, where first holes 1511 are formed in the first porous conductive layer 151, second holes 1521 are formed in the second porous conductive layer 152, and the first holes 1511 have diameters different from diameters of the second holes 1521.

The materials of the first porous conductive layer 151 and the second porous conductive layer 152 are gallium nitride-based materials, such as GaN, AlGaN, GaInN, AlGaInN and so on. The first porous conductive layer 151 and the second porous conductive layer 152 have different doping concentrations.

In this way, by setting the second semiconductor layer 150 as the conductive DBR structure, on the one hand, the conductive DBR structure is used as an essential part of the P-N junction in the light-emitting device, and on the other hand, when passing through the conductive DBR structure, resonance can be formed for light of a suitable wavelength, thereby improving the light-emitting efficiency.

Referring back to FIG. 2, the first semiconductor layer 120 includes a flat portion 121, a first protrusion 122 and a second protrusion 123 stacked in sequence in the vertical direction Y. The flat portion 121 is formed on the substrate 110, and the isolation layer 130 is formed on the flat portion 121 and has first through-holes 131 in the vertical direction Y. The first protrusion 122 is formed in the first through-hole 131. The second protrusion 123 is formed on the first protrusion 122. The second protrusions 123 correspond to the first through-holes 131 one by one, and the second protrusions 123 are spaced apart from each other. The side surface 1231 of the second protrusion 123 is a bevel, for example, the side surface of the second protrusion 123 is inclined towards the direction close to the center of the second protrusion 123. The active layer 140, the second semiconductor layer 150, and the first electrode 160 are stacked sequentially on the second protrusion 123 of the first semiconductor layer 120.

In this way, by setting the side surface 1231 of the second protrusion 123 of the first semiconductor layer 120 as a bevel, the sidewalls of the active layer 140, the second semiconductor layer 150, and the first electrode 160 formed on the outer surface of the second protrusion 123 are all beveled, thereby achieving the effect that the sidewall of the final epitaxial structure is a bevel. By setting the sidewall of the epitaxial structure as a bevel, not only a reflection angle can be provided, but also the area of the reflective surface can be increased, so that more light can be reflected to the light-emitting surface, thereby improving the light-emitting efficiency. It should be noted that by setting the side surface of the second protrusion of the first semiconductor layer as a bevel, the sidewalls of the active layer 140, the second semiconductor layer 150, and the first electrode 160 formed on the outer surface of the second protrusion 123 are all beveled, thus achieving the effect that the sidewall of the final epitaxial structure is beveled; and, by setting the sidewall of the active layer 140 as a bevel, the light-emitting area of the light-emitting device can be increased without increasing the size of the light-emitting device.

Moreover, since the active layer 140, the second semiconductor layer 150, and the first electrode 160 are all formed corresponding to the second protrusions 123 of the first semiconductor layer 120, epitaxial structures spaced apart from each other whose number is equal to the number of the second protrusions 123 are eventually formed. The width w of the second semiconductor layer 150 in each epitaxial structure is less than or equal to 200 μm, preferably, less than or equal to 100 μm.

Optionally, the second protrusion 123 is shaped as a cone, a truncated circular cone, a pyramid or a frustum of a pyramid, for example, a hexagonal frustum of pyramid or a hexagonal pyramid.

In embodiments, an angle between the side surface 1231 of the second protrusion 123 and the horizontal plane is a first angle α, and the first angle α has a degree range of 40 degrees to 70 degrees.

It should be noted that each second protrusion 123 can be formed not only on the first protrusion 122 corresponding to the second protrusion 123, but also on a part of the isolation layer 130 located at the outer periphery of the first protrusion 122 at the same time.

The sidewall 1311 of the first through-hole is beveled, and an angle between the sidewall 1311 of the first through-hole and the horizontal plane is a second angle β. The second angle β has a degree range of 0 degree to 90 degrees. The inclined direction of the sidewall 1311 of the first through-hole 131 is the same as the inclined direction of the side surface 1231 of the second protrusion 123, thereby avoiding that the light path of light reflected from the sidewall of the epitaxial structure to the light-emitting surface is blocked, thereby further improving the light-emitting efficiency.

In this embodiment, a transparent electrode is also provided between the second semiconductor layer 150 and the first electrode 160 to improve the contact between the second semiconductor layer 150 and the first electrode 160. The material of the transparent electrode is Indium tin oxide (ITO).

The material of the first semiconductor layer 120 is a gallium nitride-based material such as GaN, AlGaN, GaInN, AlGaInN and so on.

The isolation layer 130 is further provided with a second through-hole 132 in the vertical direction, and the second electrode 170 is formed in the second through-hole 132 and is connected to the first semiconductor layer 120. The materials of the first electrode 160 and the second electrode 170 may be Cr, Al, Ti, or Pt.

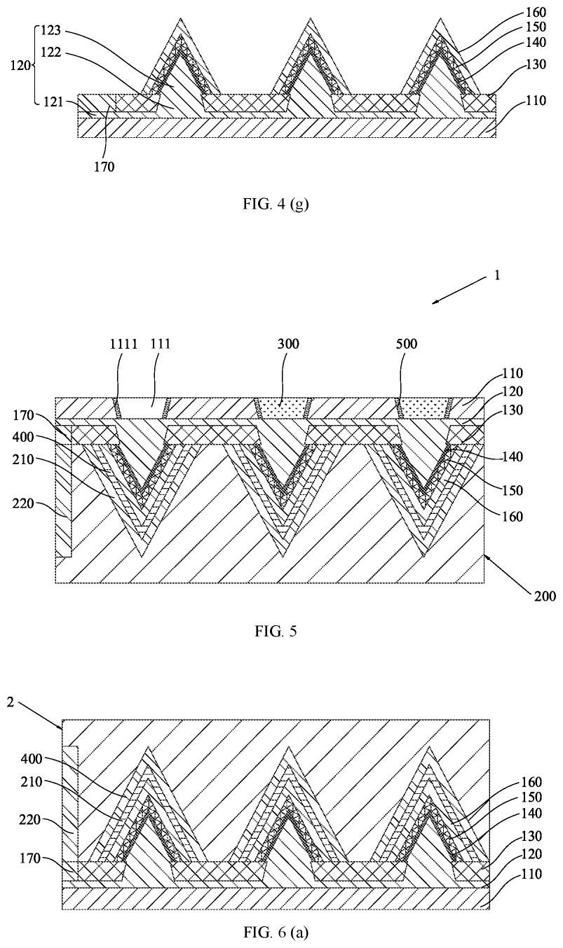

FIG. 4(a)-FIG. 4(g) are process flow diagrams of a method for manufacturing the semiconductor structure according to Embodiment 1 of the present application. The manufacturing method is used to manufacture the semiconductor structure as described above. The method for manufacturing a semiconductor structure includes the following steps S10 to S40.

At step S10, the flat portion of the first semiconductor layer is formed on the substrate; the isolation layer is formed on the flat portion of the first semiconductor layer, the first through-holes are formed in the isolation layer; the first protrusions of the first semiconductor layer are formed in the first through-holes respectively, and the second protrusions of the first semiconductor layer are formed on the first protrusions respectively.

At step S20, the active layer is formed on the second protrusions of the first semiconductor layer.

At step S30, the second semiconductor layer having a conductivity type opposite to a conductivity type of the first semiconductor layer is formed on the active layer.

At step S40, the first electrode is formed on the second semiconductor layer, the second through-hole is formed in the isolation layer, and the second electrode connected to the first semiconductor layer is formed in the second through-hole, thereby forming the semiconductor structure.

Specifically, the step S10 includes the following steps S11 to S14.

At step S11, as shown in FIG. 4(a), through a first epitaxial growth, a flat portion 121 of the first semiconductor layer 120 is formed on the substrate 110, where a surface of the flat portion 121 away from the substrate 110 is flat.

At step S12, as shown in FIG. 4(b), an isolation layer 130 is formed on the flat portion 121 of the first semiconductor layer 120, and first through-holes 131 is formed in the isolation layer 130.

At step S13, as shown in FIG. 4(c), through a second epitaxial growth, the first semiconductor layer 120 continues to grow in the first through-hole 131 of the isolation layer 130 and on the isolation layer 130 until that the surface of the first semiconductor layer 120 away from the substrate 110 is grown into a plane, where the part of the first semiconductor layer 120 located in the first through-hole 131 of the isolation layer 130 is the first protrusion 122 of the first semiconductor layer 120.

At step S14, as shown in FIG. 4(d), the surface of the first semiconductor layer 120 away from the substrate 110 is etched until that the isolation layer 130 is exposed to form the second protrusion 123 of the first semiconductor layer 120.

However, the formation of the second protrusion 123 is not limited to this. In an example, by adjusting the growth parameters of the first semiconductor layer 120 or using a mask, the first protrusion 122 of the first semiconductor layer 120 is first formed in the first through-hole 131 of the isolation layer 130, and then the second protrusion 123 with a beveled sidewall is directly formed on the first protrusion 122 without the etching step.

At step S20, as shown in FIG. 4(e), by selective growth, the active layer 140 is formed on the second protrusions 123 of the first semiconductor layer 120, so that the active layer 140 is formed only on the surfaces of the second protrusions 123 to achieve the effect that the sidewall of the active layer 140 is also beveled. In addition, through selective growth, the non-radiative compounding of the sidewall due to Inductively Coupled Plasma (ICP) etching in the conventional process can be effectively avoided.

At step S30, as shown in FIG. 4(f), through selective growth, a second semiconductor layer 150 having an opposite conductivity type to the first semiconductor layer 120 is formed on the active layer 140, so that the second semiconductor layer 150 is formed only on the surface of the active layer 140 to achieve the effect that the sidewall of the second semiconductor layer 150 is also beveled.

At step S40, as shown in FIG. 4(g), through selective growth, a first electrode 160 is formed on the second semiconductor layer 150, so that the first electrode 160 is formed only on the surface of the second semiconductor layer 150 to achieve the effect that the sidewall of the first electrode 160 is also beveled.

### Embodiment 2

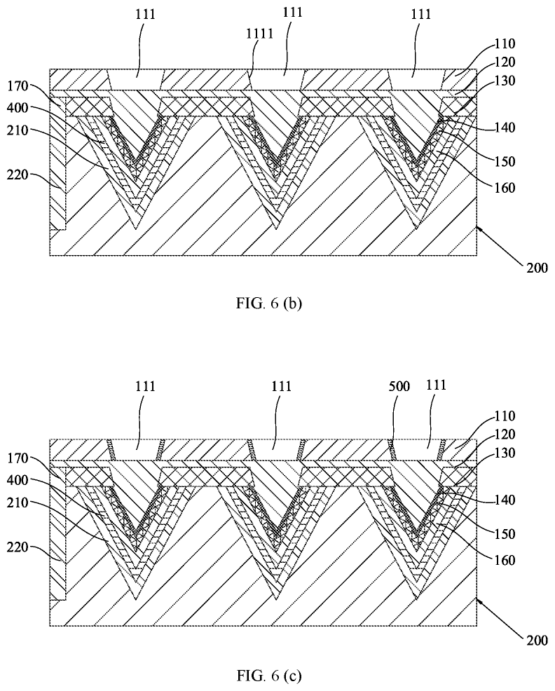

As shown in FIG. 5, the embodiment provides a light-emitting device that includes the semiconductor structure 100 in Embodiment 1, and the light-emitting device in the embodiment further includes a circuit board 200, a reflective layer 500, and a wavelength conversion dielectric layer 300.

The circuit board 200 is provided with a first solder pad 210 and a second solder pad 220, the first electrode 160 of the semiconductor structure 100 is connected to the first solder pad 210 on the circuit board 200, and the second electrode 170 of the semiconductor structure 100 is connected to the second solder pad 220 on the circuit board 200.

Third through-holes 111 are provided on the surface of the substrate 110 away from the first semiconductor layer 120, and the third through-holes 111 correspond to the first through-holes 131 respectively. Preferably, the sidewall 1111 of the third through-hole is beveled to further improve the light-emitting efficiency.

The sidewall 1111 of the third through-hole 111 is covered by the reflective layer 500 to further improve the light-emitting efficiency.

A wavelength conversion dielectric layer 300 is provided in at least one of the third through-holes 111. The wavelength conversion dielectric layer 300 includes a first wavelength conversion dielectric layer 300 and a second wavelength conversion dielectric layer 300, the first wavelength conversion dielectric layer 300 and the second wavelength conversion dielectric layer 300 convert light of different wavelengths. The wavelength conversion dielectric layer 300 is specifically set according to the design requirements, such as when the light-emitted from the active layer 140 is blue light, one or more first wavelength conversion dielectric layers 300 that can convert blue light to red light can be set in a part of the third through-holes 111, one or more second wavelength conversion dielectric layers 300 that can convert blue light to green light can be set in a part of the third through-holes 111, and some third through-holes 111 are not provided with the wavelength conversion dielectric layer 300, and thus blue light still emits from the some third through-holes 111.

In other embodiments, the reflective layer 500 may not be provided, and one or more wavelength conversion dielectric layers 300 is provided directly in the third through-holes 111.

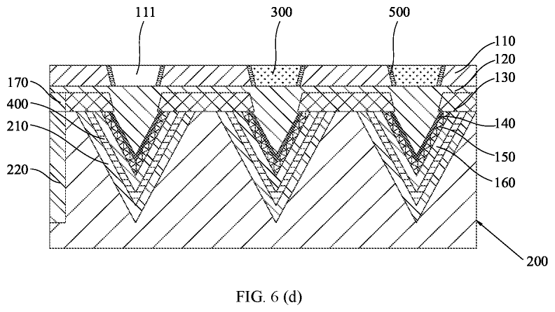

As shown in FIG. 6(a) to FIG. 6(d), another aspect of the embodiment further provides a method for manufacturing the light-emitting device. The method for manufacturing the light-emitting device includes the method for manufacturing the semiconductor structure of Embodiment 1 and further includes following steps S50-S70.

At step S50: as shown in FIG. 6(a), the semiconductor structure 100 is arranged at the front surface of the circuit board 200. The circuit board 200 is provided with a first solder pad 210 and a second solder pad 220, the first electrode 160 of the semiconductor structure 100 is connected to the first solder pad 210 on the circuit board 200, and the second electrode 170 of the semiconductor structure 100 is connected to the second solder pad 220 on the circuit board 200. Specifically, due to the large area of the first electrode 160, the first electrode 160 of the semiconductor structure 100 can be connected to the first solder pad 210 on the circuit board 200 by the conductive adhesive 400.

Before proceeding to the next step, the substrate 110 can be thinned to reduce the thickness of the whole device.

At step S60: as shown in FIG. 6(b), third through-holes 111 are provided in a surface of the substrate 110 away from the first semiconductor layer 120, the third through-holes 111 correspond to the first through-holes 131 respectively. The sidewall 1111 of the third through-hole can be set to be beveled to further improve the light-emitting efficiency.

Before proceeding to the next step, as shown in FIG. 6(c), a reflective layer 500 can be formed on the sidewall 1111 of the third through-hole 111 to further improve the light-emitting efficiency.

At step S70: as shown in FIG. 6(d), a wavelength conversion dielectric layer 300 is formed in at least one of the third through-holes 111.

According to the light-emitting device 1 and the manufacturing method therefor in the present application, by setting the second semiconductor layer as a conductive DBR structure, on the one hand, the conductive DBR structure is used as an essential part of the P-N junction in the light-emitting device, and on the other hand, by the conductive DBR structure, resonance can be formed for light of a suitable wavelength, thereby improving the light-emitting efficiency. At the same time, by setting the sidewall of the epitaxial structure as a bevel, not only a reflection angle can be provided, but also the area of the reflective surface can be increased, so that more light can be reflected to the light-emitting surface, thereby improving the light-emitting efficiency. It should be noted that by setting the side surface 1231 of the second protrusion 123 of the first semiconductor layer 120 to be beveled, the sidewalls of the active layer 140, the second semiconductor layer 150, and the first electrode 160 formed on the outer surfaces of the second protrusion 123 are all beveled, thereby achieving the effect that the sidewall of the final epitaxial structure is beveled.

According to the semiconductor structure and the method for manufacturing the semiconductor structure, the light-emitting device and the method for manufacturing the light-emitting device provided by the present application, by setting the second semiconductor layer as a conductive DBR structure, on the one hand, the conductive DBR structure is used as an essential part of the P-N junction in the light-emitting device, and on the other hand, by the conductive DBR structure, resonance can be formed for light of a suitable wavelength, thereby improving the light-emitting efficiency. At the same time, by setting the sidewall of the epitaxial structure as a bevel, not only a certain reflection angle can be provided, but also the area of the reflective surface can be increase, so that more light can be reflected to the light-emitting surface, thereby improving the light-emitting efficiency. It should be noted that by setting the side surface of the second protrusions of the first semiconductor layer as a bevel, the sidewalls of the active layer, the second semiconductor layer, and the first electrode formed on the outer surfaces of the second protrusions are all beveled, thus achieving the effect that the sidewall of the final epitaxial structure is beveled; and, by setting the sidewall of the active layer to be beveled, the area of the light-emitting device can be increased without increasing the size of the light-emitting device.

The above-mentioned embodiments are merely some embodiments of the present application, and are not used to limit the present application. Any modification, equivalent replacement, improvement, etc. made within the spirit and principles of the present application shall be included in the scope of protection of the present application.

1. A semiconductor structure, comprising: a substrate, a first semiconductor layer, an isolation layer, an active layer, a second semiconductor layer, a first electrode and a second electrode, wherein the first semiconductor layer has a conductivity type opposite to a conductivity type of the second semiconductor layer, and the second semiconductor layer is a conductive Distributed Bragg Reflector (DBR) structure;
the first semiconductor layer comprises a flat portion, first protrusions and second protrusions which are stacked sequentially in a vertical direction, the flat portion is formed on the substrate, the isolation layer is formed on the flat portion and comprises first through-holes in the vertical direction, the first protrusions are formed in the first through-holes respectively, the second protrusions are formed on the first protrusions respectively, the second protrusions correspond to the first through-holes respectively, the second protrusions are spaced apart from each other, and a side surface of each of the second protrusions is a bevel;
the active layer, the second semiconductor layer, and the first electrode are sequentially stacked on the second protrusions of the first semiconductor layer; and
the isolation layer is further provided with a second through-hole in the vertical direction, and the second electrode is formed in the second through-hole and is connected to the first semiconductor layer.

2. The semiconductor structure according to claim 1, wherein,
the conductive DBR structure is a porous conductive DBR structure,
the porous conductive DBR structure comprises one or more first porous conductive layers and one or more second porous conductive layers which are alternately stacked and formed after electrochemical corrosion,
the one or more first porous conductive layers each has first holes,
the one or more second porous conductive layers each has second holes, and
one of the first holes has a diameter different from a diameter of one of the second holes.

3. The semiconductor structure according to claim 2, wherein materials of the one or more first porous conductive layers and the one or more second porous conductive layers are gallium nitride-based materials.

4. The semiconductor structure according to claim 1, wherein an angle between the side surface of each of the second protrusions and a horizontal plane is a first angle, and the first angle have a degree range of 20 degrees to 70 degrees.

5. The semiconductor structure according to claim 4, wherein a sidewall of each of the first through-holes is a bevel, and the sidewall of the first through-hole is inclined in a same direction as the side surface of the second protrusion.

6. The semiconductor structure according to claim 1, wherein each of the second protrusions is shaped as a cone, a truncated circular cone, a pyramid or a truncated pyramid.

7. The semiconductor structure according to claim 1, wherein a transparent electrode is further provided between the second semiconductor layer and the first electrode.

8. The semiconductor structure according to claim 1, wherein a material of the first semiconductor layer is a gallium nitride-based material.

9. A light-emitting device, comprising:
a semiconductor structure according to any one of claim 1,
a circuit board and a wavelength conversion dielectric layer;
wherein the circuit board is provided with a first solder pad and a second solder pad, the first electrode of the semiconductor structure is connected to the first solder pad on the circuit board, and the second electrode of the semiconductor structure is connected to the second solder pad on the circuit board;
a surface of the substrate away from the first semiconductor layer is provided with third through-holes, the third through-holes correspond to the first through-holes respectively, and the wavelength conversion dielectric layer is provided in at least one of the third through-holes.

10. The light-emitting device according to claim 9, wherein a sidewall of each of the third through-holes is a bevel.

11. The light-emitting device according to claim 9, wherein the light-emitting device further comprises a reflective layer covered on a sidewall of one of the third through-holes.

12. A method for manufacturing a semiconductor structure,
wherein the method is used to manufacture a semiconductor structure according to any one of claim 1, and comprises:
S1: forming the flat portion of the first semiconductor layer on the substrate; forming the isolation layer on the flat portion of the first semiconductor layer, forming the first through-holes in the isolation layer; forming the first protrusions of the first semiconductor layer in the first through-holes respectively, and forming the second protrusions of the first semiconductor layer on the first protrusions respectively;
S2: forming the active layer on the second protrusions of the first semiconductor layer;
S3: forming the second semiconductor layer having the conductivity type opposite to the conductivity type of the first semiconductor layer on the active layer; and
S4: forming the first electrode on the second semiconductor layer; forming the second through-hole in the isolation layer, and forming the second electrode connected to the first semiconductor layer in the second through-hole, thereby forming the semiconductor structure.

13. The method for manufacturing the semiconductor structure according to claim 12, wherein,
in step S2, through selective growing, forming the active layer on the second protrusions of the first semiconductor layer;
in step S3, through selective growing, forming the second semiconductor layer having the conductive type opposite to the conductive type opposite of the first semiconductor layer on the active layer; and
in step S4, through selective growing, forming the first electrode on the second semiconductor layer.

14. A method for manufacturing a light-emitting device,
wherein the method for manufacturing the light-emitting device comprises a method for manufacturing the semiconductor structure according to claim 12, and further comprises:
S5: mounting the semiconductor structure to a front side of a circuit board, the circuit board being provided with a first solder pad and a second solder pad, connecting the first electrode of the semiconductor structure to the first solder pad on the circuit board, and connecting the second electrode of the semiconductor structure to the second solder pad on the circuit board;
S6: forming third through-holes on a surface of the substrate away from the first semiconductor layer, wherein the third through-holes correspond to the first through-holes respectively;
S7: forming a wavelength conversion dielectric layer in at least one of the third through-holes.

15. The method for manufacturing the light-emitting device according to claim 14, wherein a sidewall of each of the third through-holes is a bevel.

16. The method for manufacturing the light-emitting device according to claim 15, wherein after step S6 and before step S7, further comprising:
forming a reflection layer on a sidewall of one of the third through-holes.

17. The semiconductor structure according to claim 1, wherein an angle between the side surface of each of the second protrusions and a horizontal plane is a first angle, and the first angle have a degree range of 40 degrees to 70 degrees.

18. The semiconductor structure according to claim 1, wherein a width w of the second semiconductor layer is less than or equal to 200 μm.

19. The semiconductor structure according to claim 1, wherein a width w of the second semiconductor layer is less than or equal to 100 μm.
